(19) United States
(12) Patent Application Publication
(10) Pub. No.: US 2020/0003970 A1
(43) Pub. Date: Jan. 2, 2020

(54) GRATING COUPLERS FOR A SILICON ON INSULATOR WAVEGUIDE, AND METHODS OF DESIGNING, FABRICATING AND USING THE GRATING COUPLERS

(71) Applicant: UNIVERSITY OF SOUTHAMPTON, Hampshire (GB)

(72) Inventors: Riccardo Marchetti, Hampshire (GB); Cosimo Lacava, Hampshire (GB); Periklis Petropoulos, Hampshire (GB); Paolo Minzioni, Hampshire (GB); Graham T. Reed, Hampshire (GB); Ilaria Cristiani, Hampshire (GB)

(21) Appl. No.: 16/023,266

(22) Filed: Jun. 29, 2018

(51) Int. Cl. G02B 6/42; G02B 27/00; G03F 7/26

(52) U.S. Cl. CPC G02B 6/4215; G03F 7/26; G02B 27/0012

(57) ABSTRACT

A grating coupler is disclosed. The grating coupler comprises a grating formed in a waveguide formed in a silicon layer of a silicon on insulator photonic component. The grating has a series of sequentially arranged grating elements i, each comprising an alternating etched trench section having a length Lₑ and an etch depth e, and an unetched tooth section having a length L₀. Each grating element has a total length of Λᵢ and a fill factor Fᵢ. The fill factor Fᵢ of each grating element varies across the grating coupler according to an apodization function dependent on the location of the grating element. The total length of each grating element Λᵢ varies across the grating coupler such that the effective refractive index of each grating element causes the Bragg condition to be satisfied for all of the grating elements of the grating.

### TECHNICAL FIELD

The present disclosure relates to couplers for coupling light into and out of waveguide structures fabricated in Silicon-on-Insulator integrated photonic devices.

### BACKGROUND

Silicon photonics is currently a fast growing and increasingly mature technology that enables the production of low-cost, highly scalable integrated optical devices including circuits and components designed for applications in, for example, high speed optical communications, sensing and experimental physics. In particular, silicon photonics is revolutionizing the field of optical communications, allowing the realization of compact, low power circuits that can be seamlessly integrated to electrical circuits, thus allowing for dense integration of optical circuits.

Integrated optical components such as modulators, optical filters, photodetectors, arrayed waveguide gratings (AWGs), couplers, wavelength division multiplexers and all-optical wavelength converters have successfully been demonstrated, showing that multiple functions can be effectively integrated in a single integrated photonic chip. As these components can be now realized in μm-scale circuits, compact low power silicon photonic devices are able to replace bulk components. For example, silicon photonic optical transceivers, packaged in standard QSFP28 form factor, are now available, supporting speeds up to 100 Gb/s, usable for high speed intra-data centre connections, which allows the replacement of copper cables and other bulk components.

Although the technology is already relatively mature, some significant technical challenges need to be addressed. In particular, compatibility with the existing optical fiber infrastructure is a primary concern and a high efficiency coupling device, to enable light to be coupled from fiber to chip, is highly desirable. However, it is currently very difficult to reliably and effectively provide a high efficiency coupler from fiber to chip, for the following reason.

Considering Silicon-on-Insulator (SOI) technology, the strong refractive index difference between Si and SiO2 allows the implementation of very small, single mode waveguide structures. On one side this enables dense on-chip device integration, but on the other side it makes efficient coupling of light into and out of waveguide structures formed in the Silicon layer of the SOI wafer from another photonic component external to the silicon on insulator waveguide, such as an optical fiber, particularly challenging. The reason for this is that there is a significant difference between the mode field area of the light as it propagates in the optical fiber (≈80 μm2) and the light as it propagates in the SOI waveguides (<0.2 μm2). The large size mismatch between the optical mode of a single mode fiber (SMF) and a typical silicon photonic waveguide usually leads to large optical coupling losses that are in the range of 1.5-4 dB/coupler. These losses currently represent the main limiting factor for the practical realization of silicon photonic complex circuits.

It is in this context that the present disclosure has been devised.

### SUMMARY OF THE DISCLOSURE

The present disclosure provides extremely highly efficient integrated optical couplers that are able to interface single mode fiber to silicon photonic circuits with optical loss lower than 0.9 dB/coupler, with the methods needed to design and fabricate the couplers requiring only CMOS-compliant processes and is fully compatible with the current state of the art Silicon On Insulator (SOI) fabrication protocol, requiring no additional processing that would increase costs and limit scalability.

Currently, the most widely adopted form of coupler for coupling light into and out of an integrated silicon waveguide, has been the diffractive grating coupler. These couplers are provided by a series of diffractive grating elements formed in an integrated silicon waveguide, obtained by selectively etching sections of a straight optical integrated waveguide at a certain etch depth, thus obtaining a grating pattern (composed of a sequence of etched and non-etched regions). The etched grating allows a light beam (originating e.g. from an optical fiber, waveguide or free space) that propagates at a direction nearly perpendicular to the grating plane to be coupled to the fundamental optical mode of the integrated waveguide, and vice versa. However, these grating couplers have relatively high coupling losses, typically of 1.5 dB/device in the best case scenario.

In order to reduce this loss figure, various techniques have been proposed but they usually require additional fabrication processes that are not compliant with the standard CMOS chain, making the fabrication significantly more expensive and technically challenging. For example, it has been proposed to provide grating couplers with metallic back-reflectors. The embedded back-reflector significantly increases the device coupling efficiency, with reduced coupling losses as low as 0.7 dB/device being demonstrated. However, the additional fabrication processes required to integrate the metallic mirror present a significant drawback as these additional steps are not CMOS compatible and significantly increase the cost per unit of the final device.

However, the present disclosure builds on the simplicity and practicality of the standard CMOS fabrication approach of providing integrated grating couplers, by providing a design of a diffractive grating that can improve the coupling achieved with this technique by as much as 1 dB without complicating the fabrication process any further.

In particular, and as described in more detail below, the present disclosure provides a grating coupler for coupling light between a silicon on insulator waveguide and another photonic component external to the silicon on insulator waveguide, in which the fill factor of each grating element (representing the proportion of the grating element that is etched/unetched) varies across the grating according to an apodisation function dependent on the location of each grating element, and in which the total length of each grating element is set such that the Bragg condition is satisfied for each grating element across the grating. The apodisation function may be a linear apodisation function, so that the fill factor varies linearly across the grating. There are also disclosed photonic apparatuses comprising an SOI photonic component having an integrated waveguide formed in a silicon layer thereof, the waveguide having formed therein a grating coupler as disclosed in the present application.

There are also disclosed methods of designing the apodised grating, including a design process by which the parameters of the apodisation function and/or the etch depth that give an optimal or required coupling efficiency are selected. There are also disclosed methods of fabricating apodised gratings by selectively etching silicon in an SOI waveguide according to an apodised grating design developed in accordance with the present disclosure. Non-transitory computer readable media are disclosed for implementing in a controller the disclosed methods for the design and fabrication of the apodised gratings. Methods of using the apodised gratings are also disclosed.

The apodised grating in which the fill factor is apodised across the grating while the length of each grating element is adjusted to satisfy the Bragg condition, allows extremely high efficiency grating coupler devices to be obtained, showing coupling efficiency levels greater than 80% (i.e. less than 0.9 dB losses) without the need to use any non-CMOS compatible materials in the fabrication chain.

Aspects of the present disclosure are directed to a grating coupler for coupling light between a silicon on insulator waveguide and another photonic component external to the silicon on insulator waveguide. The grating coupler comprises a grating formed in a waveguide formed in a silicon layer of a silicon on insulator wafer, the grating having a series of sequentially arranged grating elements i, each grating element comprising an alternating etched trench section having a length Lₑ and an etch depth e, and an unetched tooth section having a length L₀, and each grating element having a total length of Λᵢ and a fill factor Fᵢ, wherein the fill factor F of a grating element i is the ratio between one of the length of the etched trench section Lₑ or the length of the unetched tooth section L₀ of the grating element i to the total length of the grating element Λᵢ. The fill factor Fᵢ of each grating element varies along a dimension of the grating coupler according to an apodization function dependent on a location of the grating element along the dimension. The total length of each grating element Λᵢ varies along the dimension of the grating coupler such that the effective refractive index of each grating element causes a Bragg condition to be satisfied for all of the grating elements of the grating.

According to one embodiment of the grating coupler, the apodization function is selected to increase a coupling efficiency of the grating coupler compared to an equivalent grating coupler having a uniform fill factor.

According to one embodiment of the grating coupler, the apodization function is a linear apodization function such that the fill factor Fᵢ of each grating element varies linearly along the dimension of the grating coupler according to a non-zero apodization factor parameter R.

According to one embodiment of the grating coupler, the etch depth e is such that a coupling efficiency available for the grating is greater than that obtained using other available etch depths.

According to one embodiment of the grating coupler, the etch depth e is such that the coupling efficiency is within 10% of an optimal coupling efficiency available for the grating.

According to one embodiment of the grating coupler, the etch depth e is such that the coupling efficiency is optimized for the grating.

According to one embodiment of the grating coupler, each parameter of the apodization function is such that a coupling efficiency available for the grating is greater than that obtained using other apodization function parameters.

According to one embodiment of the grating coupler, each parameter of the apodization function is such that the coupling efficiency is within 10% of an optimal coupling efficiency available for the grating.

According to one embodiment of the grating coupler, each parameter of the apodization function is such that the coupling efficiency is optimized for the grating.

According to one embodiment of the grating coupler, the etch depth e and each parameter of the apodization function are selected in combination such that a coupling efficiency available for the grating is greater than that obtained using other etch depth e and apodization function parameter combinations.

According to one embodiment of the grating coupler, the etch depth e and each parameter of the apodization function are selected in combination such that the coupling efficiency is within 10% of an optimal coupling efficiency available for the grating.

According to one embodiment of the grating coupler, the etch depth e and each parameter of the apodization function are selected in combination such that the coupling efficiency is optimized for the grating.

According to one embodiment of the grating coupler, the silicon on insulator waveguide comprises a silicon substrate, a buried silicon oxide layer over the silicon substrate and a silicon layer over the buried silicon layer and formed of one of silicon and one of its compounds having a waveguide formed therein, the waveguide having the grating formed therein.

According to one embodiment of the grating coupler, the grating coupler further comprises a top silicon oxide layer or other cladding layer disposed over the silicon layer.

According to one embodiment of the grating coupler, the fill factor Fᵢ of each grating element varies according to the linear apodization function equation Fᵢ=F₀−R·z, wherein F₀ is a fill factor of the first grating element, R is a non-zero apodization factor parameter, and z is a distance of the ith grating element from the start of the grating.

According to one embodiment of the grating coupler, the Bragg condition is satisfied when

$${Λ}_{i} = \frac{{λ}_{c}}{( {n}_{{eff}_{i}} - sin {θ}_{c} )} ,$$

wherein Λᵢ is a total length of the ith grating element, θ_{c} is a diffraction angle of the light for coupling between the grating, λ_{c} is a coupling wavelength and n_{eff}_{ᵢ} is an effective index of the ith grating element.

According to one embodiment of the grating coupler, n_{eff}_{ᵢ}=Fᵢ·n₀+(1−Fᵢ)·n_{E}, wherein n₀ and n_{E} are effective indices of the unetched tooth section and the etched trench section respectively.

Aspects of the present disclosure are directed to a photonic apparatus arranged to couple light between a silicon on insulator waveguide and a photonic component external to the silicon on insulator waveguide. Embodiments of the apparatus include a grating coupler as disclosed herein for coupling light between the silicon on insulator waveguide and the photonic component external to the silicon on insulator waveguide. Embodiments of the photonic apparatus comprise the photonic component external to the silicon on insulator waveguide, wherein the photonic component is arranged to couple light into and out of the waveguide with the grating coupler.

Aspects of the present disclosure are directed to a method of designing a grating coupler as disclosed herein for coupling light between a silicon-on-insulator waveguide and another photonic component external to the silicon on insulator waveguide. Embodiments of the method comprise setting a value for a coupling wavelength λ_{c} for the grating and a diffraction angle θ_{c} of the light for coupling between the grating, an initial fill factor F₀ for a first of the i grating elements, and an etching depth e; performing mode simulations to calculate n_{E} and n₀, wherein n_{E} and n₀ are the effective indices of the etched and unetched areas of the silicon wafer respectively; setting values for parameters of an apodization function for varying a fill factor Fᵢ of each grating element i along the dimension of the grating coupler dependent on the location of the grating element, each grating element i comprising an alternating etched trench section having a length Lₑ and an etch depth e, and an unetched tooth section having a length L₀, and each grating element having a total length of Λᵢ; and iteratively determining a length Lₑ of an etched trench section and an unetched tooth section L₀ for each ith grating element in turn along the dimension of the grating, such that the fill factor for each ith grating element Fᵢ is apodised so as to be varied from an initial fill factor F₀ based on the apodisation function and a distance zᵢ of the ith grating element along the dimension of the grating from the position z₀ of the first grating element; and the total length of the ith grating element Λᵢ, is set such that the Bragg condition λ_{c}=Λᵢ·(n_{eff,i}−sin θ_{c})) is satisfied for each ith grating element, wherein n_{eff,i} is an effective refractive index for the ith grating element calculated based on the simulated values of the refractive indices of the unetched tooth section n₀ and the etched trench section nₑ and on the fill factor Fᵢ for the ith grating element.

Embodiments of the method include generating data representing a design of the grating coupler as a sequence of alternating lengths Lₑ of the etched trench sections and lengths L₀ of the unetched tooth sections for each of the successively arranged ith grating elements, the values of Lₑ and L₀ being determined by the fill factor Fᵢ and the total length Λᵢ=Lₑᵢ+L₀ᵢ for each grating element.

Embodiments of the method include simulating coupling of light between the grating coupler by electromagnetic modelling of the grating coupler according to a design in use; and evaluating, using the simulation, a coupling efficiency for the grating coupler.

Embodiments of the method include evaluating, using the simulation, a transmission spectrum of the grating coupler modelled according to the design and adjusting the value of λ_{c} used to regenerate the design of the grating coupler to have a modelled transmission spectrum at a desired coupling wavelength.

Embodiments of the method include designing a plurality of the grating couplers each having a different value of the or each parameter of the apodisation function across a range of possible values for the parameters; simulating the coupling of light between each of the plurality of grating couplers having different parameters of the apodisation function; and evaluating, using the simulation, a coupling efficiency for each of the plurality of grating couplers having the different parameters of the apodisation function.

Embodiments of the method include performing the designing of and the evaluation of the coupling efficiency of the grating couplers for a plurality of values of the apodisation function parameters and the etch depth e.

Embodiments of the method include designing a plurality of the grating couplers each having a different value of the etch depth e across a range of possible etch depths; performing mode simulations to calculate n_{E} and n₀ for each of the plurality of grating couplers having different etch depths e; simulating coupling of light between each of the grating couplers having different etch depths e; and evaluating, using the simulation, a coupling efficiency for each of the plurality of grating couplers having the different etch depths e.

Embodiments of the method include that L_{E} and L_{O} are calculated according to:

$${L}_{0 , i} = \frac{λ ( {F}_{0} - R \cdot {z}_{i} )}{( {F}_{0} - R \cdot {z}_{i} ) ( {n}_{0} - sin {θ}_{c} ) + ( 1 - {F}_{0} + R \cdot {z}_{i} ) ( {n}_{E} - sin {θ}_{c} )} , \\ {L}_{E , i} = \frac{λ ( 1 - {F}_{0} + R \cdot {z}_{i} )}{( {F}_{0} - R \cdot {z}_{i} ) ( {n}_{0} - sin {θ}_{c} ) + ( 1 - {F}_{0} + R \cdot {z}_{i} ) ( {n}_{E} - sin {θ}_{c} )} , \\ and wherein$$

$${z}_{i} = {\sum }_{j = 0}^{i - 1} ( {L}_{0 , j} + {L}_{E , j} ) .$$

Aspects of the present disclosure are directed to a method of making a grating coupler as disclosed herein for coupling light between a silicon-on-insulator waveguide and another photonic component external to the silicon on insulator waveguide. Embodiments of the method comprise using a lithographic mask or write pattern, to selectively expose particular regions of the silicon on insulator waveguide; and etching the silicon on insulator waveguide to an etch depth e, to form a grating.

Embodiments of the method include fabricating the lithographic mask or write pattern to have the design produced.

Aspects of the present disclosure are directed to a method of using a grating coupler as disclosed herein for coupling light between a silicon-on-insulator waveguide and another photonic component external to the silicon on insulator waveguide. Embodiments of the method comprise arranging a light transmitting photonic component external to the silicon on insulator waveguide to direct light of wavelength λ_{c} onto the grating coupler at an angle θ_{c} to couple light into the waveguide with the grating coupler; or arranging a light receiving photonic component external to the silicon on insulator waveguide to receive light of wavelength λ_{c} from the grating coupler at an angle θ_{c} to couple light out of the waveguide with the grating coupler.

Aspects of the present disclosure are directed to a non-transitory computer-readable medium having instructions stored thereon which, when executed by a controller means, cause the controller to perform a method of designing a grating coupler as disclosed herein for coupling light between a silicon-on-insulator waveguide and another photonic component external to the silicon on insulator waveguide.

One embodiments of the method executed by the controller comprises setting a value for a coupling wavelength λ_{c} for the grating and a diffraction angle θ_{c} of the light for coupling between the grating, an initial fill factor F₀ for a first of the i grating elements, and an etching depth e; performing mode simulations to calculate n_{E} and n₀, wherein n_{E} and n₀ are the effective indices of the etched and unetched areas of the silicon wafer respectively; setting values for parameters of an apodization function for varying a fill factor Fᵢ of each grating element i along the dimension of the grating coupler dependent on the location of the grating element, each grating element i comprising an alternating etched trench section having a length Lₑ and an etch depth e, and an unetched tooth section having a length L₀, and each grating element having a total length of Λᵢ; and iteratively determining a length Lₑ of an etched trench section and an unetched tooth section L₀ for each ith grating element in turn along the dimension of the grating, such that the fill factor for each ith grating element Fᵢ is apodised so as to be varied from an initial fill factor F₀ based on the apodisation function and a distance zᵢ of the ith grating element along the dimension of the grating from the position z₀ of the first grating element; and the total length of the ith grating element Λᵢ, is set such that the Bragg condition λ_{c}=Λᵢ·(n_{eff,i}−sin θ_{c}) is satisfied for each ith grating element, wherein n_{eff,i} is an effective refractive index for the ith grating element calculated based on the simulated values of the refractive indices of the unetched tooth section n₀ and the etched trench section nₑ and on the fill factor Fᵢ for the ith grating element.

### BRIEF DESCRIPTION OF THE DRAWINGS

Certain examples of the disclosure will now be described in detail, by which the above and other features and advantages of the disclosure will become more apparent, with reference to the accompanying drawings in which:

FIG. 1 is a schematic drawing of a cross-section of a general layout of an grating coupler in a Silicon On Insulator wafer, showing the main structural elements thereof;

FIG. 2 is a schematic drawing illustrating a cross-section of an example linearly apodized grating coupler having a variable grating element length Λᵢ that varies to satisfy the Bragg condition for each grating element I in accordance with the present disclosure (top) compared to that of a linearly apodized grating with fixed element length Λ for all grating elements i (bottom);

FIG. 3 shows a process flow diagram illustrating an example method of designing apodised grating couplers in accordance with the present disclosure;

FIG. 4 is a schematic illustration showing an example system of apparatus for designing and fabricating apodised grating couplers in accordance with the present disclosure;

FIG. 5 is a contour plot showing the simulated coupling efficiency of example linearly apodized grating couplers realized in an SOI platform having a 260 nm thick silicon layer, as a function of etch depth and of the linear apodization factor R, for λ_{c}=1550 nm;

FIG. 6 is a graph plotting the simulated coupling efficiency for λ_{c}=1550 nm of example linearly apodized grating couplers as a function of etch depth realized in an SOI platform having a 260 nm thick silicon layer (upper plot) and a 220 nm silicon layer (lower plot);

FIG. 7 shows an optical micrograph of an example apodized grating coupler fabricated in accordance with the present disclosure; and

FIG. 8 is a graph plotting the simulated coupling efficiency of the example apodized grating coupler shown in FIG. 7 together with the experimental measurement of the coupling efficiency, against wave length.

### DETAILED DESCRIPTION

Hereinafter, terms that are used in the present disclosure will be briefly described, and then exemplary embodiments will be described in detail.

All terms including descriptive or technical terms which are used herein should be construed as having meanings that are known to one of ordinary skill in the art. However, the terms may have different meanings based on an intention of one of ordinary skill in the art, precedent cases, or the appearance of new technologies. In addition, some terms may be arbitrarily selected by the applicant, and in this case, the meaning of the selected terms will be described in detail herein. Thus, the terms used herein are defined based on the known meaning of the terms together with the description throughout the specification.

Further, when a part “includes” or “comprises” an element, unless there is a particular description contrary thereto, the part can further include other elements, not excluding the other elements. In the following description, terms such as “unit” and “module” indicate a component which is configured to perform at least one function or operation, wherein the unit and the block may be embodied as hardware or software or embodied by combining hardware and software.

The one or more exemplary embodiments will now be described more fully with reference to the accompanying drawings, in which exemplary embodiments are shown. The present inventive concept may, however, be embodied in many different forms, and should not be construed as being limited to the exemplary embodiments set forth herein; rather, these exemplary embodiments are described herein so that this disclosure will be thorough and complete, and will fully convey the concept of the present inventive concept to those of ordinary skill in the art. In the following description, well-known functions or constructions are not described in detail since they would obscure the present disclosure with unnecessary detail, and like reference numerals in the drawings denote like or similar elements throughout the specification.

As used herein, the term “and/or” includes any and all combinations of one or more of the associated listed items. Expressions such as “at least one of,” when preceding a list of elements, modify the entire list of elements and do not modify the individual elements of the list.

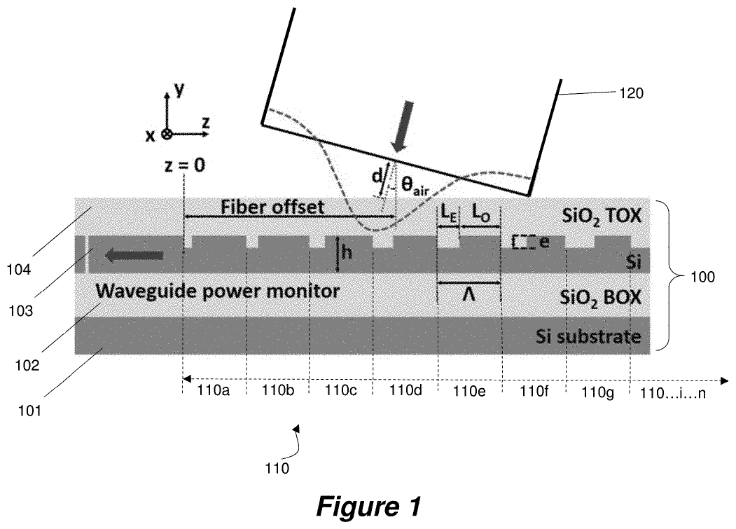

Referring now to FIG. 1, this shows a schematic drawing of a cross-section of a general layout of a grating coupler 110 formed in a Silicon On Insulator wafer 100, showing the main structural elements thereof.

The Silicon On Insulator wafer 100 is formed of a stack of at least three layers including a bulk support layer, or handle layer, 101, an electrically insulating buried oxide layer, or BOX layer, 102, and an active layer, or device layer, 103.

The handle layer 101 is typically formed of a relatively thick layer of silicon (200-1000 μm thick) serving as a support for the active wafer components above. The BOX layer 102 is typically formed of a relatively thin layer of silica SiO₂ (0.1-20 μm thick), serving to isolate the device layer 103 from the handle layer 101. The device layer itself 103 is formed of a typically thin layer of silicon or one of its compounds such as silicon nitride or silicon germanium (typically 150-700 nm thick) which can be etched, and patterned and doped to form one or more photonic active or passive integrated photonic components in an optical circuit in the device layer 103, which may also include one or more integrated electronic components to form a hybrid device. The device layer material may comprise one or more of a top oxide TOX layer, or cladding layer, 104, of silica may be formed on top of the device layer to protect and isolate the photonic components formed thereon.

Silicon is transparent to infrared light above 1.1 μm and can therefore transmit light, for example, at 1300 nm or 1550 nm, emitted by laser diodes and VCSELs, for communications and networking applications.

To guide the light within the device layer 103, the device layer 103 can be etched down to the BOX layer 102 to form a strip (or at least partway down to form a rib) configured to guide the light along the remaining unetched silicon device layer material as in a waveguide. The relatively high refractive index of silicon of around 3.5 provides tight optical confinement of light within the silicon waveguide, whereas the relatively low refractive index of silica of around 1.44 in the BOX layer and cladding ensures that the guided light undergoes total internal reflection as it passes along the waveguide.

Referring again to FIG. 1, the cross section of the SOI wafer 100 is along a section of the device layer incorporating a waveguide. The waveguide is typically on the order of a few hundreds of nm in width, but in the area shown in FIG. 1, the waveguide has been tapered out to 12 μm in width and into which a diffractive grating coupler 110 has been etched.

The diffractive grating coupler 110 is provided of a series of grating elements 110a, 110b, 110c . . . 110n (referred to herein generally grating elements 110i) formed and sequentially arranged in the tapered section of the waveguide. Each grating element 110i has an alternating etched trench section having a length Lₑ and an etch depth e, and an unetched tooth section having a length L₀ and an unetched height h.

Each grating element thus has a total length of Λ=L₀+Lₑ, and a fill factor F which is the ratio between the length of the unetched tooth section L₀ (or the etched trench section Lₑ) to the total length of the grating element Λ.

In a conventional (uniform) grating coupler, the grating elements are formed by etching plural trenches having a length Lₑ and depth e in a silicon waveguide of an SOI device layer with a constant periodicity, such that the total length Λ and fill factor F of each grating element i is constant.

Here, the effective refractive index of the grating, n_{eff}, can be expressed as shown in Equation (1).

n_{eff}=F·n₀+(1−F)nₑ (1)

where n₀ and nₑ are the effective indices of the original silicon device layer slab and the etched areas respectively.

As light passing through the waveguide intersects the grating coupler, the periodic refractive index change between the trench sections and the adjacent un-etched teeth sections allows the optical mode propagating in the silicon waveguide to be diffracted to free space in a direction dependent on the geometry of the grating elements and their effective refractive index, such that each grating element acts as a scattering or radiative unit.

In particular, the diffraction behaviour of the light in relation to the grating elements is given by the Bragg condition, which relates the diffraction angle of the light in air θₐᵢᵣ coupled into or out of the grating to the wavelength of the coupled light λ_{c}, the refractive index of the grating n_{eff} and the total length of each grating element Λ. That is, as given by the first order Bragg condition shown in Equation (2), the central angle of coupling light in/out of the grating is that at which diffracted light from each grating coupler constructively interferes.

$$Λ = \frac{{λ}_{c}}{( {n}_{eff} - sin {θ}_{c} )} \qquad ( 2 )$$

Thus a photonic component external to the silicon on insulator waveguide, such as an optical fiber 120 may couple light into or out of the grating coupler 110 if it is aligned with the coupler at a coupling beam angle of incidence of θ_{c}.

However, the main drawbacks of conventional uniform grating couplers are their narrow bandwidth (usually between 30-40 nm, less than half of edge-coupling solutions) and the relatively low coupling efficiency (CE), which is usually lower than 61% (a 2.15 dB loss). The relatively low coupling efficiency can be attributed to two main factors: grating directionality and mode mismatch. Considering a beam coupling from the SOI waveguide to a fiber, a low grating directionality 65%) means that a large percentage of the optical power incident on the grating coupler is diffracted towards the substrate (≈35%) instead of being sent towards the fiber. The mode mismatch limitation is due to the fact that the optical intensity profile radiated by a uniform grating shows an almost exponential-decay shape with a reduced overlap integral with the mode profile (almost Gaussian) of standard optical fibers.

In order to improve the coupling efficiency of conventional uniform grating couplers without introducing any additional non-CMOS compliant processes, it is possible to tailor the amount of optical power scattered by each element of the grating, so as to reduce the mode mismatch between the radiated field profile and the optical mode in a single-mode fiber. Approaches to achieving this have been proposed to vary either the etching depth or the fill-factor of each grating element, and to optimise the grating design of the varied etching depth and fill factor using a complicated Genetic Algorithm as an optimisation method starting from a simple starting structure. These techniques, in addition to being computationally intensive and time-consuming, do not allow a real physical insight as to why a particular pattern of grating fill factors for etching the sequential grating element yields an increase in coupling efficiency. However, this approach of using Genetic Algorithms alone can still not achieve an increase in coupling efficiency to a level close to that achieved by the use of back reflectors.

The present disclosure, however, provides an approach to designing and fabricating grating couplers having a non-uniform grating pattern that is not computationally intensive and gives a significant improvement in coupling efficiency that follows directly from the physical design principles.

That is, in accordance with the present disclosure, grating couplers can be designed and fabricated in which:

(a) the fill factor Fᵢ of each grating element i varies across the grating coupler according to an apodization function dependent on the location of the grating element; and
(b) the total length Λᵢ of each grating element i varies across the grating coupler such that the effective refractive index of each grating element causes the Bragg condition to be satisfied for all of the grating elements of the grating.

In detail, starting from the basic structure of a uniform GC, in accordance with the present disclosure, the fill factor F of the grating elements i is adjusted across the grating coupler in accordance with an apodization function such that each grating element i has a different fill factor Fᵢ, such that the grating is apodised. The parameters of the apodization function may be set in the design process so as to define the apodization of the grating elements (i.e. the setting of the fill factor) across the grating. In examples, the apodization function is a linear apodization function having an apodization factor R, where the apodization function is set out in Equation (3) below.

Fᵢ=F₀−R·zᵢ (3)

where Fᵢ is the fill-factor of the grating element i, F₀ is the initial fill-factor of the first grating element (i.e. the first radiative unit i=0), R is the linear apodization factor and zᵢ is the distance of the grating element i from the starting point of the grating (i.e. z₀).

Using a linear apodization function to linearly vary the value of Fᵢ across the grating elements i provides advantageous effects that the amount of optical power radiated by the first elements of the grating is reduced, and that the optical impedance matching between the waveguide and the grating section is improved. However, while linear apodization and the advantages resulting therefrom is used as a detailed example in this disclosure, the apodization function is not limited to being a linear function. Rather the apodization function may be any appropriate mathematical function that may have similar advantageous effects that can be defined and determined using a deterministic algorithm, such that the function is determined by a set of parameter values or chosen constants, and provides a unique output value for any input value in its domain.

Referring again to FIG. 1, it can be seen that the grating coupler 110 is linearly apodized such that the successive grating elements 110a,b,c . . . n have a decreasing fill factor, or rather, the etched section becomes proportionally longer.

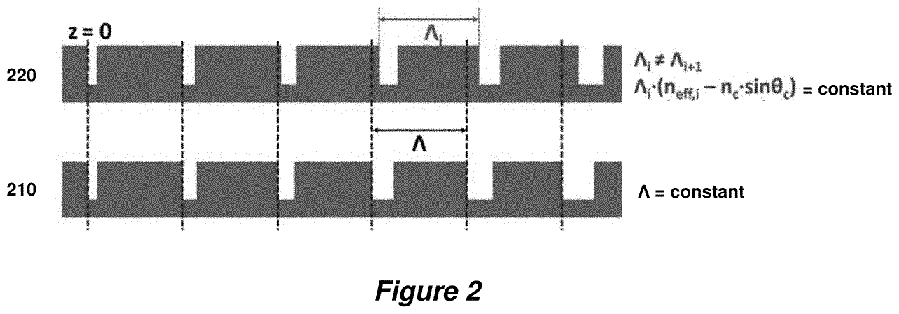

Referring to FIG. 2 now to look in more detail at the grating coupler design, here there is shown a grating coupler 210 formed of a series of linearly apodized grating elements in which the fill factor is decreased linearly for each grating element i as with increasing distance from the starting location z₀ of the first grating element i=0, such that the grating elements have an etched trench section that forms an increasingly larger proportion of the grating elements. The dotted lines indicate the start of each successive grating element, and as can be seen, in the linearly apodized grating as shown in 210, the spacing between these is even. It is important to highlight that Equation (3) describes the evolution of F along the grating, but does not impose any limitation on Λ, the grating element length. Thus, a uniform grating coupler adapted to have a linearly apodised fill factor as shown in 210 will have a uniform grating element size, such that the total grating element length Λ is constant.

However, in accordance with the present disclosure, it is recognized that, where a grating coupler is linearly apodized and Λ is constant along the whole grating as for conventional gratings, this arrangement leads to the Bragg condition not being satisfied along the length of the grating. That is, as F is varied along the grating, it is hereby realised that the effective index n_{eff} of each grating element resultingly changes, which causes the Bragg condition to no longer be satisfied across the grating and instead, the Bragg condition is satisfied only at a specific point of the grating (not along the whole structure). As a result, the coupling of light into and out of the apodized grating coupler 210 is actually less efficient than for a uniform coupler, which is why an additional loss of 1.2 dB results.

To achieve an increased coupling efficiency from apodised grating couplers without using genetic algorithms or non-CMOS compliant processing, the present disclosure provides an additional requirement in the design of the grating coupler that has a linear apodisation of F that the total grating element length Λ is not constant, but is instead a parameter that is varied along the structure, so as to satisfy the Bragg condition along the whole grating. That is shown in the grating coupler 220 of FIG. 2, which is aligned at z₀ with the grating coupler 210, but in which it can be seen that, as the index of the grating elements increases, the start of each grating element i of the grating coupler 220 becomes increasingly out of alignment with the start of each grating element i of the grating coupler 210. This is despite the fill factor of the equivalent grating elements being the same between the grating couplers 210 and 220. The reason for this is that the total length of each grating element Λᵢ is not constant, such that Λᵢ≠Λᵢ₊₁.

Thus instead of maintaining the total length of each grating element Λᵢ constant prevents the grating from satisfying the Bragg condition simultaneously for all the grating elements, the grating coupler 220 is designed and fabricated such that the total length of each grating element Λᵢ is adjusted for the apodized fill factor Fᵢ for that grating element, such that the Bragg condition is satisfied for that grating element. That is, for each grating element i, in addition to the fill factor Fᵢ being apodized, the total length of each grating element Λᵢ is adjusted in accordance with the Bragg condition in Equation (4).

$${Λ}_{i} = \frac{{λ}_{c}}{( {n}_{{eff}_{i}} - sin {θ}_{c} )} \qquad ( 4 )$$

Or, expressed another way:

Λᵢ·(n_{eff}_{ᵢ}−sin θ_{c})=λ_{c}=constant (5)

where n_{eff}_{ᵢ} is the effective refractive index of the grating element i, which is not constant across the grating due to the apodised fill factor.

To calculate the effective index n_{eff}_{ᵢ} of each grating element, according to the chosen level of etch depth e, Equation (6) is used, which is a modification of Equation (1).

n_{eff}_{ᵢ}=F·n₀+(1−Fᵢ)nₑ (6)

The values of n₀ and nₑ are extracted from mode simulations of slab waveguides having height respectively equal to h and h−e, h being the thickness of the silicon device layer of the wafer, for the non-etched (teeth) and etched (trenches) areas respectively. Consequently, while n₀ is a constant value, nₑ depends on the etch depth e, and consequently also n_{eff} is a function of e.

Using the obtained values of n_{eff} for a given etch depth from mode simulations and from Equation (6), given apodization function parameters (e.g. a value of R for linear apodisation) and for a beam to be coupled in/out of the integrated waveguide coupler with a given wavelength λ_{c} (e.g. 1550 nm) and a given coupling angle of incidence θ_{c} (e.g. 14.5 degrees), the length of the tooth section L_{0,i} and the length of the trench section L_{e,i} of each grating element i can be calculated using Equation (4).

Specifically, combining Equation (3) for the fill factor for each grating element i, Equation (4) for the Bragg condition for each grating element i, and using the relation and rearranging the terms, Λᵢ=L_{Ei}+L_{Oi}, L_{Ei} and L_{Oi} may be calculated according to Equations (7) and (8).

$$\begin{matrix}{L}_{0 , i} = \frac{λ ( {F}_{0} - R \cdot {z}_{i} )}{( {F}_{0} - R \cdot {z}_{i} ) ( {n}_{0} - sin {θ}_{c} ) + ( 1 - {F}_{0} + R \cdot {z}_{i} ) ( {n}_{E} - sin {θ}_{c} )} & ( 7 ) \\ {L}_{E , i} = \frac{λ ( 1 - {F}_{0} + R \cdot {z}_{i} )}{( {F}_{0} - R \cdot {z}_{i} ) ( {n}_{0} - sin {θ}_{c} ) + ( 1 - {F}_{0} + R \cdot {z}_{i} ) ( {n}_{E} - sin {θ}_{c} )} \\ wherein \\ {z}_{i} = {\sum }_{j = 0}^{i - 1} ( {L}_{0 , j} + {L}_{E , j} ) & ( 8 )\end{matrix}$$

Thus in the grating couplers of the present disclosure, the grating fill-factor is varied along the grating propagation distance, in examples according to a linear apodization factor R, and, at the same time, the length Λ of each grating element is varied to compensate for the effective refractive index change (caused by the fill-factor apodization) and to satisfy the Bragg condition at the required central wavelength. As will be shown below, this allows extremely high efficiency grating coupler devices to be obtained, showing efficiency levels greater than 80% without the need to use any non-CMOS compatible materials or processes in the fabrication chain.

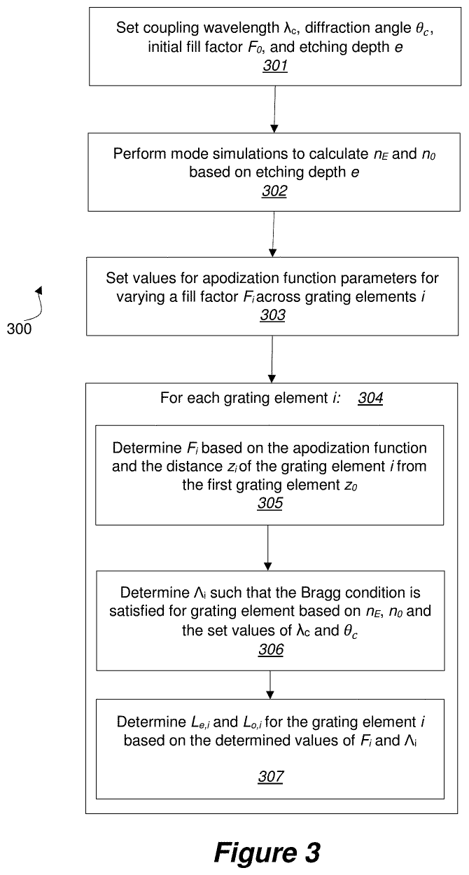

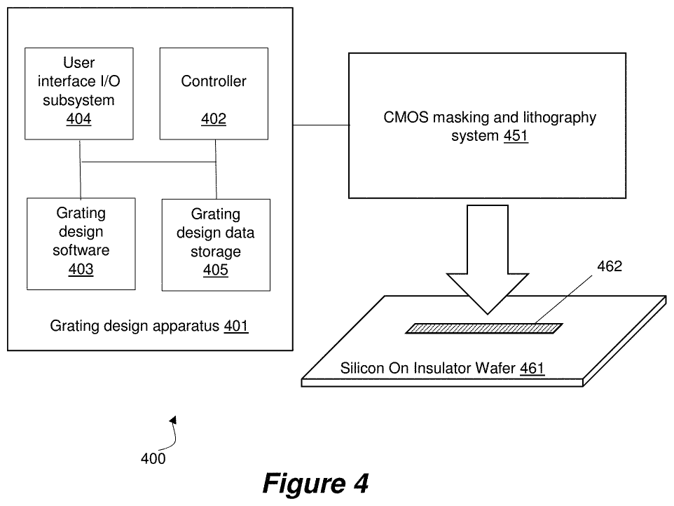

A method of designing a grating coupler in accordance with the present disclosure, and a system for designing and fabricating the grating coupler will now be described in detail in relation to FIGS. 3 and 4.

Referring to FIG. 4, a system 400 for designing and fabricating a grating coupler in accordance with the present disclosure comprises a grating design apparatus 401 coupled to provide a grating design to a CMOS masking and lithography system 451 for etching an apodised grating pattern 462 in an integrated waveguide in a device layer of a SOI wafer 461.

The grating design apparatus 401 may be any suitable apparatus configured for implementing the method described below in relation to FIG. 3. That is, the apparatus controls a design process to produce a grating design represented as data usable by a CMOS masking and lithography system 451 to selectively etch the SOI wafer according to the design.

In the example shown in FIG. 4, the grating design apparatus 401 is a general purpose computer comprising a controller 402 which may be provided by one or more data processors and a non-transitory computer readable medium 403 storing grating design software as a set of instructions which when executed by the controller 402, cause the controller to operate the method described in relation to FIG. 3. The one or more data processors providing the controller 402 may be general purpose microprocessors such as x8086 CPUs or may be microcontrollers or Field Programmable Gate Arrays to some degree specifically configured to implement the method of FIG. 3, or some combination thereof.

The grating design apparatus 401 may further comprise a user interface input/output subsystem 404 for providing an operator of the grating design apparatus with a user interface, such as a graphical user interface (GUI), by which the operator may define inputs to and review outputs from the grating design process. Of course, the user interface input/output subsystem 404 may not be provided and the inputs to the grating design process may be pre-configured in for example the non-transitory computer readable medium 403 or received at the grating design apparatus 401 through a data transfer over a wired or wireless network, or by means of coupling to a physical storage medium.

Thus, with reference to FIG. 3, once configured by the grating design software 403, the controller carries out the method 300 for designing the apodised grating as follows. While the method 300 presents the sub processes apparently sequentially, it will be understood that the sub processes may be performed out of sequence or in parallel.

In 301, the controller sets the values for the coupling wavelength λ_{c}, diffraction angle θ_{c}, initial fill factor F₀ for the first of the i grating elements, and etching depth e. One or more of these may be user configured, by user control of the grating design apparatus 401 through user interface input/output subsystem 404, or one or more of these values may be preset. For example, the user may set the coupling wavelength λ_{c} and diffraction angle θ_{c} based on the required configuration of the grating coupler in the context of the photonic device (e.g. the wavelength of the VCSEL or laser diode light to be coupled into/out of the photonic integrated circuit (PIC), and the arrangement of the external fiber waveguide). It is worth noting that the coupling wavelength λ_{c} and diffraction angle θ_{c} represent the wavelength and angle values at the interface between the grating of the silicon waveguide and the material facing the waveguide. For example, where a silica TOX cladding layer 104 is provided, the values of coupling wavelength λ_{c} and diffraction angle θ_{c} may be different from the values for the wavelength and diffraction angle on exit from the external waveguide where the light exits the fiber into air or another index coupling material.

The values of initial fill factor F₀, and etching depth e may be pre-set, or as will be explained in more detail below, in the case in which the apparatus 401 is being operated and process 300 is being carried out to optimise the grating coupler design to achieve a desired or a maximum possible coupling efficiency, the value of the etching depth e in particular may be iteratively adjusted or swept across a range of possible etch depths by the apparatus 401 under control of the grating design software 402.

Then, in 302, the apparatus is configured to perform mode simulations to calculate n_{E} and n₀, wherein n_{E} and n₀ are the effective refractive indices of the etched and unetched areas of the silicon device layer of the SOI wafer respectively. This is based on the height h of the silicon in the device layer, where n₀ is calculated for a silicon layer of height h, and n_{E} is calculated for an etched height of h−e. A suitable model constructed in a physics or photonics modelling platform, such as MODE Solutions™ available from Lumerical Inc., of Suite 1700, 1095 W. Pender St., Vancouver, BC V6E 2M6 Canada, may be operated to perform the modelling of the effective refractive indices.

In 303, the apparatus is configured to set values for parameters of the apodization function for varying a fill factor Fᵢ of each grating element i across the grating coupler dependent on the location of the grating element. The apodization function may be pre-defined or selected by user control, and similarly the parameters thereof may be pre-defined or selected by user control. For example, the apodization function may be set to be a linear apodization function as in Equation (3), and the value of the linear apodization factor R may be set accordingly. As with the value of the etch depth e, in the case in which the apparatus 401 is being operated and process 300 is being carried out to optimise the grating coupler design to achieve a desired or a maximum possible coupling efficiency, the value of the apodization function parameters (such as a linear apodization factor R) may be iteratively adjusted or swept across a range of possible apodization factor parameters by the apparatus 401 under control of the grating design software 402.

At this stage, the apodization function parameters, and the other set parameters λ_{c}, θ_{c}, F₀, e, n_{E} and n₀ may be stored in a cache of the controller 402 or in the non transitory computer readable medium 403 and used to control the grating design process for determining a length Lₑ of an etched trench section and an unetched tooth section L₀ for each ith grating element of the grating as follows, which may be implemented in controller as a deterministic algorithm.

In 304, for each ith grating element in turn across the grating, the apparatus iteratively determines a length Lₑ of an etched trench section and an unetched tooth section L₀. This determination is controlled such that:

1. the fill factor for each ith grating element Fᵢ is apodised so as to be varied from the initial fill factor F₀ based on the apodisation function and a distance z of the ith grating element along the grating from the position z₀ of the first grating element; and
2. the total length of the ith grating element Λᵢ, is set such that the Bragg condition λ_{c}=Λᵢ·(n_{eff,i}−sin θ_{c}) is satisfied for each ith grating element, wherein n_{eff,i} is the effective refractive index for the ith grating element calculated based on the simulated values of the refractive indices of the unetched tooth section n₀ and the etched trench section nₑ and on the fill factor Fᵢ for the ith grating element;

In more detail, in examples, the determination of Lₑ and L₀ for each grating element i in turn (starting from i=0) may be performed by, in 305, determining Fᵢ using equation (3), i.e. based on the apodization function (as defined by the apodization function parameters) and the distance zᵢ of the grating element i from the first grating element z₀.

Then, in 306, the apparatus 401 may determine the total length Λᵢ of the grating element i such that the Bragg condition is satisfied for grating element i, using Equation (5) to determine n_{eff}_{ᵢ} from n_{E}, n₀, and using Equation (6) and the set values of λ_{c} and θ_{c}.

Then, in 307, the apparatus 401 may determine the values of L_{e,i} and L_{0,i} for each grating element based on the values of Fᵢ and Λᵢ determined from 305 and 306 (i.e. Fᵢ·Λᵢ=L_{0,i} and (1−Fᵢ)·Λᵢ=L_{e,i}).

Once the values of L_{e,i} and L_{0,i} have been determined for the grating element i, the steps 305, 306 and 307 can be determined for the grating element i+1 in the next iteration, where zᵢ₊₁=zᵢ+Λᵢ.

Alternatively to the steps 305, 306 and 307, or in addition, the values of L_{e,i} and L_{0,i} may be determined in one shot for each grating element i in turn using algorithms implementing Equations (7) and (8) above. Other appropriate methods and algorithms for determining the Lₑ and L₀ for each grating element i to satisfy the constraints (a) and (b) above may be implemented without limitation.

In 307, the output data of the values of L_{e,i} and L_{0,i} for each grating element i may be stored by the apparatus 401 as grating design data in the grating design data storage 405, which may be any suitable non-transitory computer readable medium such as a flash memory. This may be a sequence of grating measurement values stored in a table or a suitable data structure usable by CMOS masking and lithography system 451 to selectively etch the SOI wafer to a depth e according to the stored design. For example, the data representing the design of the grating coupler may be generated in 307 and stored as a sequence of alternating lengths Lₑ of the etched trench sections and lengths L₀ of the unetched tooth sections for each of the successively arranged ith grating elements.

In the present disclosure, it is possible to operate the design apparatus 401 and method 300 so as to select a grating coupler design that achieves a desired coupling efficiency. The selected grating coupler design may be that which is expected (e.g. through modelling) to achieve the maximum coupling efficiency, a coupling efficiency within e.g. 2%, 4%, 6%, 8% or 10% of the maximum coupling efficiency available for the grating.

In particular, considering the standard situation where the thickness h of the Si device layer 103 and the thickness of the BOX layer 102 are imposed by the available SOI wafers, the only design parameters that need to be optimized are the etch depth e and the parameters of the apodization function. In the case of a linear apodization function, only two parameters need to be optimized: the etch depth e and the apodization factor R. This is rather different and significantly more straightforward computationally compared to approaches to grating coupler design that rely on genetic algorithm optimization techniques, which specify and optimize the lengths of the etched and un-etched portions of each grating element individually in order to optimize the coupling efficiency as a whole, which lead to optimization problems over a wide range of interrelated parameter spaces, which are complicated and can lead to sub-optimal and unusual solutions, with no physical insight as to why that coupling efficiency is obtained.

Thus, in examples of the present disclosure, the apodization function may be selected to increase the coupling efficiency of the grating coupler compared to an equivalent grating coupler having a uniform fill factor. In examples in which the apodization function is a linear apodization function, the non-zero apodization factor parameter R is optimized to improve coupling efficiency.

In order to assess and optimize the coupling efficiency of a range of possible apodised grating coupler designs in accordance with the present disclosure, the grating design software 403 may further configure the controller 402 to simulate the coupling of light between the grating coupler by electromagnetic modelling of the grating coupler according to the design in use; and evaluating, using the simulation, a coupling efficiency for the grating coupler. These simulations may be performed again using a suitable physics or photonics modelling platform such as using a fully vectorial 2D-Finite Difference Time Domain (FDTD) simulations using FDTD Solutions™ from Lumerical Inc., of Suite 1700, 1095 W. Pender St., Vancouver, BC V6E 2M6 Canada.

In examples, the method may further comprise evaluating, using the simulation, the transmission spectrum of the grating coupler modelled according to the design. In certain cases it may be found that the peak coupling efficiency of the grating coupler does not occur precisely at the coupling wavelength λ_{c} used in the grating design. In this case, the method may further comprise adjusting the value of λ_{c} used to regenerate the design of the grating coupler to have a modelled transmission spectrum preferably centred at the desired coupling wavelength.

In embodiments, the apodization function parameters may be sweeped to give optimal coupling efficiency for one or more given etch depths. Thus, in order to optimize the grating design, the method may comprise designing a plurality of grating couplers each having a different value of the or each parameter of the apodisation function across a range of possible values for the parameters. For example, for a linear apodisation function, a plurality of grating coupler designs may be produced using the method 300 each for one of a range of apodization factors R.

The method may further include simulating the coupling of light between each of the plurality of grating couplers having different parameters of the apodisation function; and evaluating, using the simulation, a coupling efficiency for each of the plurality of grating couplers having the different parameters of the apodisation function.

In embodiments, the etch depth e may be sweeped to give optimal coupling efficiency for one or more given values of the apodization function parameter(s). Thus in order the optimize the grating design, the method may comprise designing a plurality of the grating couplers, each having a different value of the etch depth e across a range of possible etch depths. The method may further include performing mode simulations to calculate n_{E} and n₀ for each of the plurality of grating couplers having different etch depths e and simulating the coupling of light between each of the grating couplers having the different etch depths e; and evaluating, using the simulation, a coupling efficiency for each of the plurality of grating couplers having the different etch depths e.

Once these coupling efficiencies have been evaluated for the range of different etch depths and values of the one or more apodization function parameters, to optimize the coupling efficiency, a grating design may be selected having a value for the or each parameter of the apodization function (e.g. an R value) and for the etch depth e which results in a coupling efficiency higher than that for grating couplers having other apodization function parameters (e.g. other R values) and etch depths e. The coupling efficiency may be optimized by selecting the values for the one or more apodization function parameters and the etch depth e when looking at the resulting coupling efficiencies together or independently. In particular, in examples, the method further comprises determining the optimal etch depth e and/or optimal apodization function parameter values to give the highest coupling efficiency.

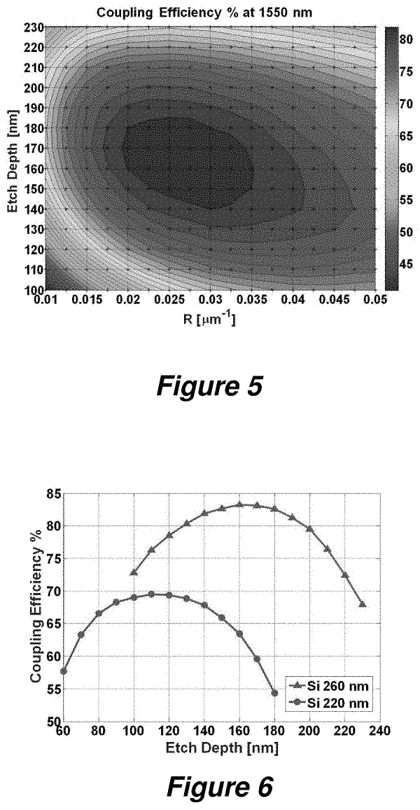

To illustrate the coupler design, optimisation and fabrication process, an example will now be described with reference to FIGS. 5, 6, 7 and 8.

In the example, the apodized grating design is a linearly apodized grating design that has a length of the grating elements controlled such that the Bragg condition is satisfied across length of the grating. In the example, the grating is designed for coupling a beam of light at λ_{c}=1550 nm between a fiber 120 arranged above a grating coupler 110 to be formed in a waveguide of a silicon device layer 103 of an SOI wafer 461. The SOI wafer 461 having a 2 μm-thick buried SiO2 BOX layer 102 having a refractive index of 1.44 at 1550 nm and the silicon device layer 103 having a refractive index of 3.48 at 1550 nm and a thickness h of 260 nm. A top SiO2 TOX cladding layer, also having a refractive index of 1.44 at 1550 nm, was included in the layout, having a height of 680 nm. Trenches forming the grating coupler were assumed to be completely filled by the TOX cladding and no index-matching liquid was considered between the TOX cladding and the fiber. An angle of incidence of coupled light of θ_{c}=10 degrees was set in the TOX layer 104 (corresponding to an angle of incidence of the fiber 120 in air above the TOX cladding layer 104 of 14.5 degrees).

The value of the initial fill factor F₀ for the first grating may be selected in order to maximise coupling efficiency, but it may typically be set to correspond to an initial trench size matching the minimum features size achievable by the CMOS masking and lithography system 451. In the example, this corresponds to a minimum etched feature size of 60 nm, which gives a value of F₀ of 0.9.

These parameters for the coupling grating, having been set in the grating design apparatus 401 using user interface input/output subsystem 404, then enabled a plurality of grating designs to be produced by operating controller 402 based on grating design software 403 and the set parameters, for a plurality of 10 nm spaced etch depths e in a range of etch depths from 100 to 230 nm, and a plurality of 0.0025 μm⁻¹ spaced linear apodization factor values R in a range of linear apodization factor values from 0.01 to 0.05 μm⁻¹. The etch depth e and the linear apodization factor value R were swept together, to arrive at grating designs for all possible combinations thereof. For each of these designs, the Bragg condition is satisfied across the length of the grating due to the design process.

To evaluate the coupling efficiency of the plurality of grating designs for each value of e and R, fully vectorial 2D-FDTD simulations using FDTD Solutions™ from Lumerical Inc. were carried out by creating a model of each grating design in use in accordance with FIG. 1. In the model, the coupling efficiency was evaluated by considering the grating as an in-coupling device, i.e. coupling light from the SMF 120 into the SOI waveguide by means of the grating coupler, and a physical model of the SOI etched with the coupler designs was produced. In accordance with the model, the fiber 120 (which was assumed to have an outer diameter of 125 μm and a mode field diameter (MFD) of 10.4 μm), was tilted by θₐᵢᵣ=14.5 degrees with respect to the vertical direction (corresponding to an incidence angle on the grating θ_{c}=10 degrees in the TOX), causing the Gaussian beam output from the fiber 120 to impinge on the TOX with a MFD of about 10.8 μm. In the model, the electric field of the Gaussian beam was polarized along the x direction with reference to FIG. 1, so that the incoming light could be coupled to the fundamental TE mode of the integrated waveguide. A frequency-domain power monitor, positioned along the Si waveguide at a 10 μm distance from the grating, was used in the model to measure the amount of optical power coupled to the waveguide.

The coupling efficiency of the different grating configurations was calculated while simultaneously sweeping both the etch depth e, by 10 nm steps, and the apodization factor R, by 0.0025 μm⁻¹ steps. For every grating configuration the offset of the fiber mode from the starting point of the grating was also optimized.

FIG. 5 shows an illustration of the simulation results in a contour plot of the coupling efficiency shown as a heat map, plotted against the simulated range of the parameters e and R.

FIG. 6 shows, in the upper plot thereof, effectively a cutaway through this contour plot data by plotting on a graph of the coupling efficiency against the range of etch depths for a constant apodization factor R of 0.0425 μm⁻¹·(The lower plot shows an equivalent curve for simulations for grating couplers in a different SOI having a 220 nm thick silicon device layer.)

It can be noticed in the upper plot of FIG. 6 that, starting from an etch depth of 100 nm, the peak (i.e. maximum) coupling efficiency is found to be 73% (representing a loss of −1.4 dB) when the apodization factor R is equal to 0.0425 μm⁻¹.

However, referring to the full data in the contour plot, it can be seen that the peak in the coupling efficiency across all values of e and R can be achieved to maximise the coupling efficiency at 83% (representing a loss of only −0.8 dB) for e=160 nm and R=0.025 μm⁻¹. If the etch depth is further increased, the coupling efficiency starts to decrease, with a value of 68% (−1.7 dB) when e=230 nm and R=0.025 μm⁻¹. Significantly, as can be seen, the simulated coupling efficiency is higher than 80% for a wide range of (e, R) combinations, thus showing a good tolerance to small variations in the fabrication process. This is not necessarily the case for genetic algorithm-derived solutions which tend to be less stable and tolerant of manufacturing variations, meaning that the coupling efficiency can drop off significantly for these GA-derived grating designs even within normal manufacturing tolerances.

The same procedure used for the design of the optimized apodized grating coupler based on the 260 nm SOI platform, was also applied to the 220 nm SOI grating, achieving a maximum coupling efficiency of 70% (−1.6 dB) when e=110 nm and R=0.0275 μm⁻¹. It can be seen that by using a SOI platform with the thicker of the two Si layers it is possible to obtain a higher CE, and that deep etching levels (110 nm and 160 nm for the 220 nm and 260 nm SOI platforms, respectively) are required to obtain the maximum CE.

Further simulations of the optimised 260 nm SOI waveguide operating as an outcoupling device were conducted, placing a fundamental-mode waveguide source in the Si waveguide, a power-monitor above the grating coupler to assess its directionality and an additional power-monitor in the Si-layer to assess grating reflectivity by measuring the optical power reflected back in the waveguide. The simulated directionality and reflectivity results were compared with those modelled for an equivalent uniform (non-apodised) grating (having a constant fill factor F=0.5 and grating element length) realized in the same SOI platform, and a 10% improvement in the directionality maximum was observed for the apodised grating of the present disclosure, with a significantly reduced reflectivity.

An example apodized grating design encoded by grating design data 405 for passing to the CMOS masking and lithography system 451 is shown in Table 1. This is the linearly apodized grating design that, as described above, has been optimized to give a maximum coupling efficiency for an SOI wafer 461 having a 260 nm thick silicon device layer 103 for a wavelength of coupled light of λ_{c}=1550 nm, and an angle of incidence of coupled light of θ_{c}=10 degrees in the TOX layer 104 (corresponding to an angle of incidence of the fiber in air above the TOX cladding layer 104 of 14.5 degrees). As can be seen, the value of the initial fill factor F₀=0.9 corresponds to an initial trench size in the first period of 60 nm, matching the minimum feature size achievable by the CMOS masking and lithography system 451 available to the applicant for fabrication and experimental testing of the optimized grating design.

TABLE 1

| Period | L_{E} (nm) | L_{O} (nm) |
|---|---|---|
| 1 | 60 | 540 |
| 2 | 69 | 533 |
| 3 | 79 | 526 |
| 4 | 88 | 520 |
| 5 | 98 | 513 |
| 6 | 108 | 506 |
| 7 | 118 | 498 |
| 8 | 128 | 491 |
| 9 | 138 | 484 |
| 10 | 148 | 477 |
| 11 | 159 | 469 |
| 12 | 170 | 461 |
| 13 | 180 | 454 |
| 14 | 191 | 446 |
| 15 | 203 | 438 |
| 16 | 214 | 430 |
| 17 | 225 | 422 |
| 18 | 237 | 413 |
| 19 | 249 | 405 |
| 20 | 261 | 396 |
| 21 | 273 | 387 |
| 22 | 286 | 378 |
| 23 | 298 | 369 |
| 24 | 311 | // |

Once the apodised grating design has been produced by the process in 300, which may have been selected in an optimization process to achieve an optimized coupling efficiency in the SOI wafer for processing (as in the design of Table 1), the grating design data 405 may be passed to the CMOS masking and lithography system 451. In the example experiment, the data corresponding to the grating design set out in Table 1 was passed to the CMOS masking and lithography system 451, together with an indication of the etch depth e=160 nm.

Here, the CMOS masking and lithography system 451 uses a lithographic mask or write pattern, designed based on the grating design data 405 input to it from the grating design apparatus 401, to selectively etch particular regions of the silicon on insulator waveguide to correspond to the etched trench sections of the coupler specified in the design. This may be achieved in any suitable known way without limitation by, for example, selectively illuminating a photoresist layer formed on the surface of the SOI wafer 461 using a photolithographic mask, and washing away the illuminated areas of the photoresist to expose the device layer of the silicon on insulator waveguide 461 in a pattern corresponding to the grating coupler design data 405 (in the example experiment, as represented in Table 1). Then the CMOS masking and lithography system 451 may perform one or more chemical etches of the exposed sections to the etch depth e specified by the design data 405 (in the example experiment e=160 nm), to form a grating in the silicon waveguide having etched trench sections according to the selected waveguide design. Any other suitable process for selectively etching the grating design into the Si device layer waveguide may be used, without limitation. The SOI waveguide may subsequently be clad with a TOX cladding layer.

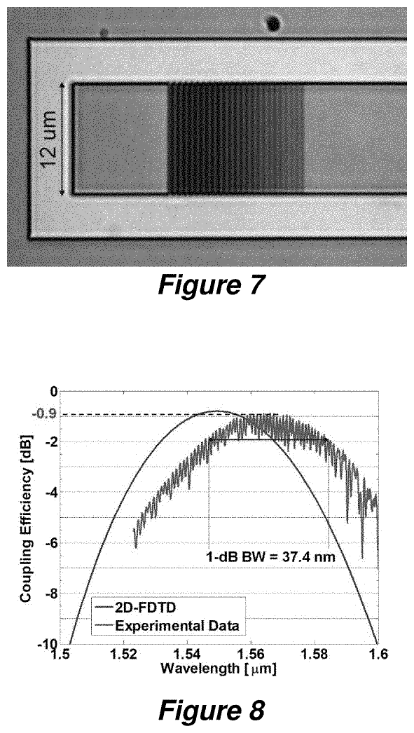

In this way, in the experiment, the grating coupler design shown in Table 1 yielding the highest coupling efficiency in a 260 nm Si-thick SOI platform was fabricated (in which e=160 nm, F₀=0.9, R=0.025 μm⁻¹). An optical micrograph of this is shown in FIG. 7. As can be seen, the fabricated grating was 12 μm wide along the x direction, to properly accommodate the Gaussian mode of the fiber, and 14.847 μm long across the 24 grating elements in accordance with the design. In accordance with the grating design 220 shown in FIG. 2, the fabricated grating design is linearly apodised and the total length of each grating element is controlled to satisfy the Bragg condition across the length of the grating.

To assess the coupling efficiency of the fabricated gratings, they were formed as part of designed integrated structures composed of two of the grating couplers, connected by waveguides (500 nm wide). Two such structures were fabricated, with the only difference being that the connecting waveguides had different lengths of 5.2 mm and 30.2 mm, so as to allow separation out of the loss contributions resulting from beam propagation from those resulting from beam coupling. The waveguides were connected to the gratings by 500 μm long linear tapers. In the fabrication process in the experiment, the CMOS masking and lithography system 451 used Electron Beam Lithography (E-beam) to define the grating pattern in accordance with the design, and Inductively-coupled plasma (ICP) dry etching to etch and define the final grating structures. A protective TOX layer was finally deposited by means of plasma enhanced chemical vapor deposition (PECVD).

The experimental characterization was carried out by means of a vertical coupling scheme, using polarization maintaining (PM) single mode fibers aligned at the angle of incidence in air of 14.5 degrees to couple light into and out of the devices using the two grating couplers. The optical source was a PM external cavity laser (ECL), tunable from 1523 to 1600 nm at 5 μm steps, and a power meter was used to measure the output optical power collected from the test structures. The grating coupling efficiency was obtained by subtracting the waveguide propagation loss from the measured fiber-to-fiber transmission and dividing by two (thus assuming that the input and output coupling losses were equal).

One of the measured coupling efficiency curves as a function of wavelength is shown in FIG. 8 (right plot), together with the 2D-FDTD simulation result for the grating. The parasitic amplitude ripple affecting the grating transmission spectrum may be caused by the transition between the taper and the single-mode waveguide. As can be seen, the maximum experimental coupling efficiency for the fabricated device was measured to be −0.9 dB, showing a very good agreement with the theoretical coupling efficiency values (−0.8 dB, i.e. 83%), and indicating a good consistency in the fabrication process. Further, the measured −1 dB bandwidth of the device of 37.4 nm is rather wide.

Further experiments were carried out with different optimized grating designs in accordance with the present disclosure being fabricated on different SOI platforms. Measurements carried out on the several different structures, from four different chips, obtaining an average coupling efficiency of −1.1 dB, and a maximum coupling efficiency of −0.9 dB (for the grating coupler shown in FIG. 7).

It is worth highlighting that the experimentally measured coupling efficiency for the optimized grating coupler in accordance with the present disclosure (−0.8 dB theoretical, −0.9 dB observed) is better than that achieved in apodized grating structures that have a constant grating element length in an equivalent Si-depth SOI platform (−2.7 dB theoretical and observed). Similarly, the losses achieved in the present disclosure are less than that observed for a Genetic-Algorithm derived grating design in an equivalent Si-depth SOI platform (−1.0 dB theoretical) and are much easier to design and reliably fabricate.

Further, the losses achieved in the present disclosure are even better than the best loss value experimentally obtained (−1.2 dB) using fill-factor apodization (but constant grating element length) in a thicker 340 nm Si-thick SOI wafer. While in theory, this apodized structure in a thicker 340 nm Si-thick SOI wafer is predicted to obtain losses of −0.8 dB, the relatively large deviation between theoretical and experimental data can probably be associated to the high aspect ratio of the required trenches (>4.5 compared to 2.7 in the structures of the present disclosure), whose proper fabrication can be quite challenging.

Further, the level of the losses achieved in the grating couplers of the present disclosure is also quite close the record loss value of −0.62 dB which was achieved using an Al back-reflector in a 250 nm Si-thick SOI wafer, which requires additional, non-CMOS compliant processing to be fabricated.

Thus by designing and fabricating a grating coupler in accordance the present disclosure, a very high coupling efficiency, below the −1 dB threshold, can be obtained even without the use of any back-reflector or additional, non-CMOS compliant processing.

The grating coupler approach disclosed herein also offers significant advantages compared to the main alternative technique that does not use grating couplers, which is “edge” or “butt” coupling, in which a single mode fiber is arranged to face against and couple light into and out of a silicon photonic waveguide in an SOI wafer. This solution adopts inverse tapers to match the single mode fiber optical mode to the silicon photonic waveguide allowing a smooth transition between the fiber and the silicon photonic waveguides. In this approach, the fabrication of the coupling components on the SOI device can also be made by using CMOS compatible processes only. However, very precise alignment between the single mode fiber and the coupling device is needed in order to achieve low coupling losses. That is, while optimum alignments can lead to low coupling losses of about 0.7 dB/coupler, even a small deviation from the optimum point usually leads to a significant increase in coupling losses (typically a deviation of ±1 μm in the longitudinal axis causes 2 dB additional losses). Thus this approach is not particularly practical and has not been widely adopted.

In contrast, grating coupler devices designed in accordance with the present disclosure show only an additional 0.5 dB loss when a fiber misalignment of 1 μm is present on the longitudinal axis, leading to an −1.5 dB improvement with respect to the butt coupling approach (under similar conditions). This leads to significantly improved fiber alignment tolerances.

Further, the grating couplers of the present disclosure are easy to fabricate using standard CMOS fabrication processes and can be put anywhere on the chip, thus allowing for easier wafer-level testing, whereas edge-couplers, despite their potentially good performance in terms of coupling efficiency, restrict the chip architecture, require complicated fabrication processes (such as high-quality chip facets polishing), and show high sensitivity to fiber misalignment.

Thus the presently disclosed grating design and fabrication method allows for the first time a grating coupler to be obtained achieving coupling with less than 1 dB loss for an SOI wafer having an Si device layer thickness of less than 340 nm and without using a back-reflector.

While the claimed invention has been particularly shown and described with respect to the illustrated and preferred examples thereof, it will be understood by those skilled in the art that the foregoing and other changes in form and details may be made therein without departing from the spirit and scope of the invention.

What is claimed is:

1. A grating coupler for coupling light between a silicon on insulator waveguide and another photonic component external to the silicon on insulator waveguide, the grating coupler comprising:
a grating formed in a waveguide formed in a silicon layer of a silicon on insulator wafer, the grating having a series of sequentially arranged grating elements i, each grating element comprising an alternating etched trench section having a length Lₑ and an etch depth e, and an unetched tooth section having a length L₀, and each grating element having a total length of Λᵢ and a fill factor Fᵢ, wherein the fill factor Fᵢ of a grating element i is the ratio between one of the length of the etched trench section Lₑ or the length of the unetched tooth section L₀ of the grating element i to the total length of the grating element Λᵢ;
wherein the fill factor Fᵢ of each grating element varies along a dimension of the grating coupler according to an apodization function dependent on a location of the grating element along the dimension; and
wherein the total length of each grating element Λᵢ varies along the dimension of the grating coupler such that the effective refractive index of each grating element causes a Bragg condition to be satisfied for all of the grating elements of the grating.

2. The grating coupler of claim 1, wherein the apodization function is selected to increase a coupling efficiency of the grating coupler compared to an equivalent grating coupler having a uniform fill factor.

3. The grating coupler of claim 1, wherein the apodization function is a linear apodization function such that the fill factor Fᵢ of each grating element varies linearly along the dimension of the grating coupler according to a non-zero apodization factor parameter R.

4. The grating coupler of claim 1, wherein the etch depth e is such that a coupling efficiency available for the grating is greater than that obtained using other available etch depths.

5. The grating coupler of claim 4, wherein the etch depth e is such that the coupling efficiency is within 10% of an optimal coupling efficiency available for the grating.

6. The grating coupler of claim 5, wherein the etch depth e is such that the coupling efficiency is optimized for the grating.

7. The grating coupler of claim 1, wherein each parameter of the apodization function is such that a coupling efficiency available for the grating is greater than that obtained using other apodization function parameters.

8. The grating coupler of claim 7, wherein each parameter of the apodization function is such that the coupling efficiency is within 10% of an optimal coupling efficiency available for the grating.

9. The grating coupler of claim 8, wherein each parameter of the apodization function is such that the coupling efficiency is optimized for the grating.

10. The grating coupler of claim 1, wherein the etch depth e and each parameter of the apodization function are selected in combination such that a coupling efficiency available for the grating is greater than that obtained using other etch depth e and apodization function parameter combinations.

11. The grating coupler of claim 10, wherein the etch depth e and each parameter of the apodization function are selected in combination such that the coupling efficiency is within 10% of an optimal coupling efficiency available for the grating.

12. The grating coupler of claim 11, wherein the etch depth e and each parameter of the apodization function are selected in combination such that the coupling efficiency is optimized for the grating.

13. The grating coupler of claim 1, wherein the silicon on insulator waveguide comprises a silicon substrate, a buried silicon oxide layer over the silicon substrate and a silicon layer over the buried silicon layer and formed of one of silicon and one of its compounds having a waveguide formed therein, the waveguide having the grating formed therein.

14. The grating coupler of claim 13, wherein the device further comprises a top silicon oxide layer or other cladding layer disposed over the silicon layer.

15. The grating coupler of claim 1, wherein the fill factor Fᵢ of each grating element varies according to the linear apodization function equation Fᵢ=F₀−R·z, wherein F₀ is a fill factor of the first grating element, R is a non-zero apodization factor parameter, and z is a distance of the ith grating element from the start of the grating.

16. The grating coupler of claim 1, wherein the Bragg condition is satisfied when
$${Λ}_{i} = \frac{{λ}_{c}}{( {n}_{{eff}_{i}} - sin {θ}_{c} )} ,$$
wherein Λᵢ is a total length of the ith grating element, θ_{c} is a diffraction angle of the light for coupling between the grating, λ_{c} is a coupling wavelength and n_{eff}_{ᵢ} is an effective index of the ith grating element.

17. The grating coupler of claim 16, wherein n_{eff}_{ᵢ}=Fᵢ·n₀+(1−Fᵢ)·n_{E}, wherein n₀ and n_{E} are effective indices of the unetched tooth section and the etched trench section respectively.

18. A photonic apparatus arranged to couple light between the silicon on insulator waveguide as claimed in claim 1 and a photonic component external to the silicon on insulator waveguide, the photonic apparatus further comprising:
the photonic component external to the silicon on insulator waveguide, wherein the photonic component is arranged to couple light into and out of the waveguide with the grating coupler.

19. A method of designing a grating coupler as claimed in claim 1 for coupling light between the silicon-on-insulator waveguide and another photonic component external to the silicon on insulator waveguide, the method comprising:
setting a value for a coupling wavelength λ_{c} for the grating and a diffraction angle θ_{c} of the light for coupling between the grating, an initial fill factor F₀ for a first of the i grating elements, and an etching depth e;
performing mode simulations to calculate n_{E} and n₀, wherein n_{E} and n₀ are the effective indices of the etched and unetched areas of the silicon wafer respectively;
setting values for parameters of an apodization function for varying a fill factor Fᵢ of each grating element i along the dimension of the grating coupler dependent on the location of the grating element, each grating element i comprising an alternating etched trench section having a length Lₑ and an etch depth e, and an unetched tooth section having a length L₀, and each grating element having a total length of Λᵢ; and
iteratively determining a length Lₑ of an etched trench section and an unetched tooth section L₀ for each ith grating element in turn along the dimension of the grating, such that:
the fill factor for each ith grating element Fᵢ is apodised so as to be varied from an initial fill factor F₀ based on the apodisation function and a distance zᵢ of the ith grating element along the dimension of the grating from the position z₀ of the first grating element; and
the total length of the ith grating element Λᵢ, is set such that the Bragg condition λ_{c}=Λᵢ·(n_{eff,i}−sin θ_{c}) is satisfied for each ith grating element, wherein n_{eff,i} is an effective refractive index for the ith grating element calculated based on the simulated values of the refractive indices of the unetched tooth section no and the etched trench section nₑ and on the fill factor Fᵢ for the ith grating element.

20. The method of claim 19, further comprising generating data representing a design of the grating coupler as a sequence of alternating lengths Lₑ of the etched trench sections and lengths L₀ of the unetched tooth sections for each of the successively arranged ith grating elements, the values of Lₑ and L₀ being determined by the fill factor Fᵢ and the total length Λᵢ=Lₑᵢ+L₀ᵢ for each grating element.

21. The method of claim 19, further comprising simulating coupling of light between the grating coupler by electromagnetic modelling of the grating coupler according to a design in use; and evaluating, using the simulation, a coupling efficiency for the grating coupler.

22. The method of claim 21, further comprising evaluating, using the simulation, a transmission spectrum of the grating coupler modelled according to the design and adjusting the value of λ_{c} used to regenerate the design of the grating coupler to have a modelled transmission spectrum at a desired coupling wavelength.

23. The method of claim 21, further comprising: designing a plurality of the grating couplers each having a different value of the or each parameter of the apodisation function across a range of possible values for the parameters; simulating the coupling of light between each of the plurality of grating couplers having different parameters of the apodisation function; and evaluating, using the simulation, a coupling efficiency for each of the plurality of grating couplers having the different parameters of the apodisation function.

24. The method of claim 23, further comprising performing the designing of and the evaluation of the coupling efficiency of the grating couplers for a plurality of values of the apodisation function parameters and the etch depth e.

25. The method of claim 19, further comprising: designing a plurality of the grating couplers each having a different value of the etch depth e across a range of possible etch depths; performing mode simulations to calculate n_{E} and n₀ for each of the plurality of grating couplers having different etch depths e; simulating coupling of light between each of the grating couplers having different etch depths e; and evaluating, using the simulation, a coupling efficiency for each of the plurality of grating couplers having the different etch depths e.

26. The method of claim 19, wherein L_{E} and L₀ are calculated according to:
$${L}_{0 , i} = \frac{λ ( {F}_{0} - R \cdot {z}_{i} )}{( {F}_{0} - R \cdot {z}_{i} ) ( {n}_{0} - sin {θ}_{c} ) + ( 1 - {F}_{0} + R \cdot {z}_{i} ) ( {n}_{E} - sin {θ}_{c} )} , \\ {L}_{E , i} = \frac{λ ( 1 - {F}_{0} + R \cdot {z}_{i} )}{( {F}_{0} - R \cdot {z}_{i} ) ( {n}_{0} - sin {θ}_{c} ) + ( 1 - {F}_{0} + R \cdot {z}_{i} ) ( {n}_{E} - sin {θ}_{c} )} , \\ and wherein$$
$${z}_{i} = {\sum }_{j = 0}^{i - 1} ( {L}_{0 , j} + {L}_{E , j} ) .$$

27. A method for making the grating coupler of claim 19 for coupling light between the silicon on insulator waveguide and the photonic component external to the silicon on insulator waveguide, the method comprising:
using a lithographic mask or write pattern, to selectively expose particular regions of the silicon on insulator waveguide;
etching the silicon on insulator waveguide to an etch depth e, to form a grating.

28. The method as claimed in claim 27, further comprising fabricating the lithographic mask or write pattern to have the design produced.

29. A method for using a grating coupler as claimed in claim 1 for coupling light between the silicon-on-insulator waveguide and the photonic component external to the silicon on insulator waveguide, the method comprising one of:
arranging a light transmitting photonic component external to the silicon on insulator waveguide to direct light of wavelength λ_{c} onto the grating coupler at an angle θ_{c} to couple light into the waveguide with the grating coupler; or
arranging a light receiving photonic component external to the silicon on insulator waveguide to receive light of wavelength λ_{c} from the grating coupler at an angle θ_{c} to couple light out of the waveguide with the grating coupler.

30. A non-transitory computer-readable medium having instructions stored thereon which, when executed by a controller means, cause the controller to perform the method according to claim 19.
